(19) United States
(12) Patent Application Publication
(10) Pub. No.: US 2011/0175191 A1
(43) Pub. Date: Jul. 21, 2011

(54) ISOLATION TRENCHES FOR SEMICONDUCTOR LAYERS

(75) Inventor: Fabrizio Fausto Renzo Toia, Busto Arsizio(VA) (IT)

(73) Assignee: STMicroelectronics S.r.l., Agrate Brianza (MI) (IT)

(21) Appl. No.: 12/973,505

(22) Filed: Dec. 20, 2010

(30) Foreign Application Priority Data
Dec. 21, 2009 (IT) VI2009A000302

(51) Int. Cl. H01L 29/06; H01L 21/762

(52) U.S. Cl. 257/506; 438/424; 257/E21.546; 257/E29.02

(57) ABSTRACT

A method is for the formation of at least one isolation trench filled with thermal oxide in a semiconductor layer and a semiconductor device include at least one isolation trench filled with thermal oxide. The method allows obtaining in an easy way, isolation trenches exhibiting excellent functional morphological properties. The method is based on the idea of exploiting the properties of the thermal oxidation mechanism of a semiconductor material in order to obtain at least an isolation trench filled with thermal oxide.

### FIELD OF THE INVENTION

The present invention relates to the field of semiconductor technology. In particular, the present invention relates to a method for producing at least an isolation trench in a semiconductor layer and to a semiconductor device comprising at least an isolation trench. Still more in particular, the present invention relates to a method for the production of an isolation trench filled with thermal oxide and a semiconductor device comprising at least an isolation trench filled with thermal oxide.

### BACKGROUND OF THE INVENTION

Isolation trenches are employed in the field of integrated circuits to provide electrical insulation among the devices realized, for instance, on a single chip. For example, in the field of BCD devices (bipolar CMOS-DMOS) isolation trenches a few micrometers wide are used in order to obtain systems with high breakdown voltages, for instance of the order of 100V. The width of the isolation trenches used is one of the critical factors rendering the fabrication process of the semiconductor devices costly and elaborate.

In particular, the fabrication process of isolation trenches for semiconductor layers known in the prior art is schematically shown in FIG. 1. FIG. 1a displays a cross section of the formation of a trench 6 in a semiconductor layer 1. The trench comprises sidewalls 6r and 6l. The trench 6 is produced, for example, depositing a layer of field oxide 2 on the semiconductor layer 1 and realising the hard mask HD by means of a nitride layer 3 and a deposited-oxide layer 4. A resist layer is subsequently deposited (not shown in the figure) on the oxide layer 4. The resist is patterned, for instance by means of photolithography techniques, so as to establish the position and dimensions of the trench. A dry etching process is performed in order to remove the regions of the hard mask corresponding to the position of the trench 6 to be realized. Subsequently, the resist layer is removed and the semiconductor layer 1 is etched so as to dig the trench 6. Finally the residual attack polymers are removed.

In order to make the trench 6 isolating, it is helpful to fill it with isolating material, typically with oxide. FIGS. 1b and 1c display the way trench 6 is filled with oxide according to what is known in the prior art. First of all, the sidewalls 6l and 6r of the trench 6 are oxidized (FIG. 1b). In particular, a thermal oxidation is performed in order to cover the walls of the trench by means of a liner oxide. In practice, a new trench 6′ is obtained comprising sidewalls 6l′ and 6r′ covered by thermal oxide, i.e. by oxide produced by means of the thermal oxidation. The dashed line in FIG. 1b displays the original position of the trench 6. In order to fill the trench 6′ with oxide, a deposition of oxide 7, for instance by chemical vapour deposition, is performed (FIG. 1c). The deposition of oxide 7 implies not only the filling of the cavity of the trench 6′, but also the covering of the layer of the deposited-oxide 4 and the filling of the space above the cavity 6. Consequently, in order to remove the oxide from these regions, it is useful to employ polishing techniques such as the technique CMP (chemical mechanical polishing).

The oxide deposition process exhibits several drawbacks. Deposited-oxide, in fact, exhibits worse isolation properties than thermal oxide. Moreover, also from the morphologic point of view, deposited-oxide displays more defects and instabilities than the thermal oxide. Isolation trenches obtained with the methods known from the prior art, do not exhibit, therefore, satisfactory isolation properties. They are in fact characterized by low breakdown voltages.

Moreover, the deposition strongly limits the width of the trenches that can be obtained. In particular, for example, the deposition process is unduly costly and time consuming in case that trenches some micrometers wide are to be realized. Furthermore, the deposition process involves the subsequent polishing of the system because it is extremely difficult to precisely control the regions wherein the oxide is deposited.

### SUMMARY OF THE INVENTION

In light of the drawbacks concerning the fabrication of isolation trenches in semiconductor layers, the scope of the present invention is that of providing a method for the production of at least one isolation trench in a semiconductor layer and a device comprising at least an isolation trench allowing overcoming these problems.

In particular, the scope of present invention is that of providing a method allowing the production of isolation trenches completely filled with thermal oxide. Furthermore, a method for the production of isolation trenches allowing the easy and low costs realisation of wide isolation trenches is provided. In addition, a method allowing the production of isolation trenches exhibiting excellent isolation properties such as high structural stability and high breakdown voltages is provided. Still further, a method for the production of isolation trenches having defined and precise geometrical structures is also provided.

Another method aspect is for the production of isolation trenches exhibiting vertical structures and almost devoid of defects. Yet another method aspect is an efficient and inexpensive method for the production of isolation trenches. Further, a method for the production of isolation trenches allowing the easy realisation of trenches exhibiting different dimensions is provided. A device comprising at least an isolation trench exhibiting excellent functional and morphological properties is also provided.

The present invention relates to a method for the formation of at least an isolation trench filled with thermal oxide and a semiconductor device comprising at least an isolation trench filled with thermal oxide. The present disclosure is based on the general idea of exploiting the properties of the thermal oxidation mechanism of semiconductor materials in order to obtain at least an isolation trench filled with thermal oxide. In particular, the disclosure invention is based on the idea of considering the relationship between the consumption thickness of semiconductor material and the total thickness of the thermal oxide grown, in order to realize an isolation trench filled with thermal oxide. Still more particular, the present disclosure is based on the idea of exploiting the consumption of semiconductor material during the thermal oxidation process in order to obtain an isolation trench filled with thermal oxide. In other words, the present disclosure is based on the idea of employing portions of semiconductor material completely oxidized by means of a thermal oxidation process in order to obtain an isolation trench filled with thermal oxide.

According to a first embodiment, a method for the production of at least an isolation trench having a determined final width in a semiconductor layer is provided. The method includes fabrication in the semiconductor layer of at least a first trench and a second trench, the second trench being at a lateral distance from the first trench, and performance of a thermal oxidation process, wherein the lateral distance is adapted to completely oxidize the space between the first trench and the second trench by means of the thermal oxidation of the sidewalls of the first trench and of the sidewalls of the second trench so as to obtain a single isolation trench.

According to a further embodiment, the lateral distance between the first and the second trench is 20% or less of the final width of the isolation trench.

According to a further embodiment, the first trench has a width lower than the final width of the isolation trench and the width of the first trench is adapted to fill the first trench by means of thermal oxidation of the sidewalls of the first trench so as to obtain the single isolation trench.

According to a further embodiment, the second trench has a width lower than the final width of the isolation trench and the width of the second trench is adapted to fill the second trench by means of the thermal oxidation of the sidewalls of the second trench so as to obtain the single isolation trench.

According to a further embodiment, the width of the first trench is substantially equal to the width of the second trench. According to a further embodiment, the width of the first trench and the width of the second trench are equal to 30% or less of the final width of the isolation trench.

According to a further embodiment, a method for the production of at least an isolation trench having a determined final width in a semiconductor layer is provided. This method includes fabrication of an array of N trenches in the semiconductor layer, with N≧2, each of the trenches having a trench width and the trenches being separated by a mutual lateral distance, wherein the trench width of the trenches and the mutual distance between the trenches are adapted to oxidize the regions between the trenches and to fill each of the trenches by means of the thermal oxidation of the lateral walls of each of the trenches so as to obtain the single isolation trench.

According to a further embodiment, the trench width of each of the N trenches is 60/N percent or less of the final width of the isolation trench. According to a further embodiment, the mutual distance between the trenches of the array is 40/N percent or less of the final width of the isolation trench.

According to a further embodiment, a method for the production of at least an isolation trench having a determined final width in a semiconductor layer is provided. The method includes fabrication of at least one trench in a semiconductor layer, the trench having a top width and a bottom width, wherein the top width and the bottom width are lower than the final width of the isolation trench and performance of a thermal oxidation process wherein the top width and the bottom width are adapted to fill the trench along its depth by means of the thermal oxidation of the sidewalls of the trench so as to obtain a single isolation trench having the final width.

According to a further embodiment, the top width of the trench differs from the bottom width of the trench by 10% or less. According to a further embodiment, at least one of the top width and the bottom width of the trench corresponds to 60% or less of the final width of the isolation trench.

According to a further embodiment, a method for the production of at least an isolation trench having a determined final width in a semiconductor layer is provided. The method includes fabrication of at least two or more trenches in the semiconductor layer, the trenches being at a mutual lateral distance, the trenches having a top width and a bottom width, wherein the top width and the bottom width are lower than the final width of the isolation trench and performance of a thermal oxidation process. The mutual lateral distance between the trenches is adapted to oxidize the space between the trenches by means of the thermal oxidation of the sidewalls of the trenches and the top width and the bottom width of the trenches are adapted to fill the trenches along their depth by means of the thermal oxidation of the lateral walls of the trenches so as to obtain a single isolation trench having the final width.

According to a further embodiment, the top width of the trenches differs from the bottom width of the trenches by 10% or less. According to a further embodiment, at least one of the top width and the bottom width of the trenches corresponds to 60% or less of the final width of the isolation trench.

According to a further embodiment, a semiconductor device comprising at least an isolation trench is provided, the isolation trench having a top width and a bottom width wherein the top width differs from the bottom width by 10% or less and the isolation trench is completely filled with thermal oxide. According to a further embodiment, at least one of the top width and the bottom width of the isolation trench is larger than or equal to 2.5 μm. According to a further embodiment, the semiconductor device comprises a bipolar CMOS-DMOS BCD device.

### BRIEF DESCRIPTION OF THE DRAWINGS

FIG. 1 schematically displays the formation process of an isolation trench according to the prior art;

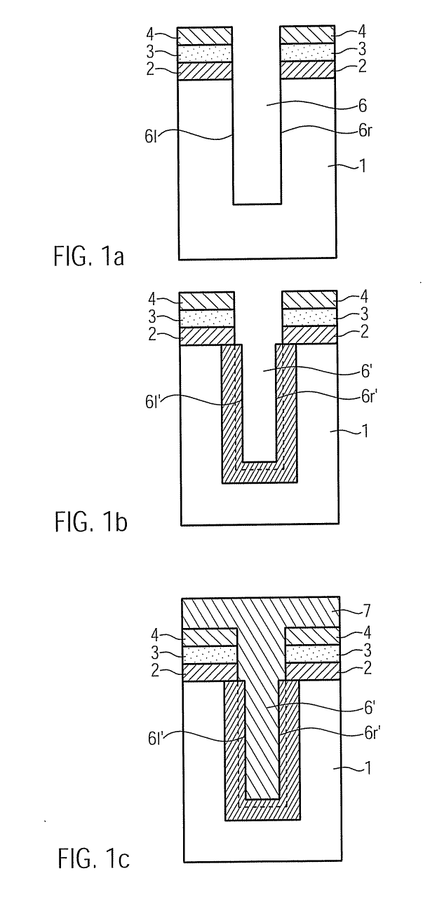

FIG. 2 schematically displays the thermal oxidation process of a surface of a silicon crystal;

FIG. 3 schematically displays a formation process of an isolation trench according to an embodiment of the present invention;

FIG. 4 schematically displays the formation process of an isolation trench according to a further embodiment of the present invention.

### DETAILED DESCRIPTION OF THE PREFERRED EMBODIMENTS

In the following, the present invention is described with reference to particular embodiments as shown in the enclosed Figures. Nevertheless, the present invention is not limited to the particular embodiments described in the following detailed description and shown in the Figures, but rather, the described embodiments simply exemplify several aspects of the present invention whose scope is defined by the claims.

Further modifications and variations of the present invention will be clear to the person skilled in the art. The present description has to be considered, therefore, as comprising all modifications and/or variations of the present invention whose scope is defined by the claims.

Corresponding elements in the Figures are indicated for simplicity with the same reference numbers. Moreover, in the following, wherein not differently specified, the horizontal direction is the direction of the surface of the semiconductor layer. Consequently, the vertical direction is the direction perpendicular to the surface of the semiconductor layer. Moreover, with the wording “top width” of a trench or of an isolation trench, the distance between the sidewalls of the trench or of the isolation trench, respectively, measured in correspondence with the opening of the trench or of the isolation trench in the semiconductor layer is meant. In other words, the top width is measured at the level of the surface of the semiconductor layer. With the wording “bottom width” of a trench or of an isolation trench, the distance between the sidewalls of the trench or of the isolation trench, respectively, measured at the base of the trench or of the isolation trench, i.e. in the terminal portion of the trench or of the isolation trench within the semiconductor layer, is meant. Moreover, wherein not differently specified, with the wording “trench width” and “isolation trench width” the mean width of the trench and of the isolation trench, respectively, are meant.

As indicated above, the present invention is based on the general idea of exploiting the properties of the thermal oxidation mechanism of a semiconductor material with the purpose of obtaining at least an isolation trench filled with thermal oxide.

The thermal oxidation process may be performed at high temperature (for example, 900° C. to 1200° C.) either exposing the system to an oxygen environment (dry oxidation) or exposing the system to an environment containing aqueous vapour (wet oxidation).

The growth of a volume of thermal oxide having final total thickness T_{OX} on a surface of a semiconductor material implies the conversion of a determined volume of semiconductor material having thickness T_{S} and the corresponding growth of a volume of thermal oxide having a thickness H_{OX} measured from the level of the original surface of the semiconductor material. This is due to the fact that the atomic density of the semiconductor material is higher than the atomic density of the thermal oxide of the semiconductor material and, therefore, the thermal oxidation implies an increase of the volume.

In synthesis:

T_{OX}=T_{S}+H_{OX} e1

The relationship between the final total thickness T_{OX} of the thermal oxide grown and the thickness T_{S} of the semiconductor material worn out is known for several semiconductor materials. In general, the thickness T_{S} corresponds to a specified percentage fraction P of the thickness T_{OX}:

$${T}_{s} = \frac{P}{100} \cdot {T}_{ox} \qquad e2$$

Consequently, combining equations e1 and e2:

$${H}_{ox} = \frac{100 - P}{100} \cdot {T}_{ox} \qquad e3$$

In the case of silicon, for example, the thickness of the silicon worn out corresponds to about 40% of the thickness T_{OX} of the thermal oxide grown (SiO₂) (i.e., in the case of silicon P=40). In particular, considering the ratio between the atomic density of crystal silicon and the atomic density of the silicon oxide (SiO₂), the value P for silicon corresponds to 44. In other words, if the level of the silicon surface to be oxidized is considered as reference level, when a thermal silicon oxide is grown with a thickness T_{OX}, a layer of silicon with a thickness T_{S} corresponding to about 40% of T_{OX} is worn out, i.e. silicon is worn out up to a depth corresponding to about 40% of T_{OX} starting from the reference level. This thickness originally occupied by silicon is converted into thermal oxide. At the same time, a layer of thermal oxide is grown above the reference level of the original silicon surface. In particular, the height H_{OX} of the grown thermal oxide measured from the original silicon surface corresponds to about 60% of T_{OX}.

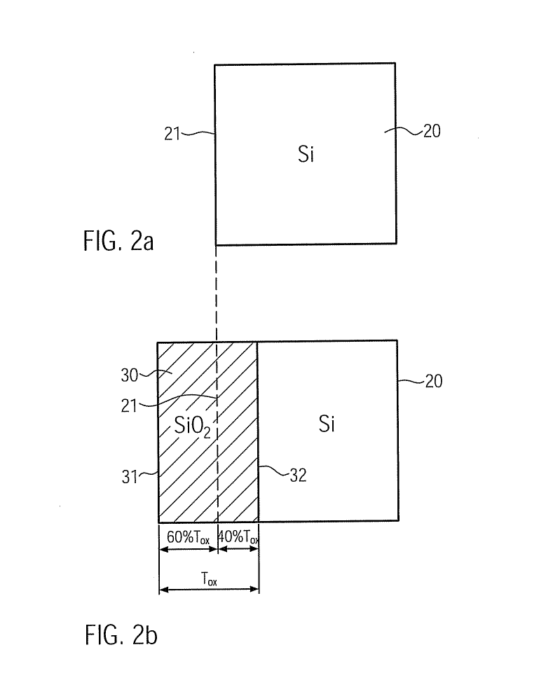

This is schematically shown in FIG. 2. FIG. 2a displays a silicon crystal 20 comprising a surface 21. FIG. 2b shows the result of the thermal oxidation of the surface 21 with the subsequent growth of the volume 30 of silicon thermal oxide (SiO₂) having a thickness corresponding to T_{OX}. The original level of the surface 21 of the silicon crystal 20 is shown by means of the dashed line in FIG. 2b. It is observed that the surface 31 of the thermal oxide is at a distance corresponding to about 60% of T_{OX} from the original level of the surface 21, while the interface 32 between the thermal oxide and the silicon crystal is at a depth corresponding to about 30% of T_{OX} with respect to the original level of the surface 21.

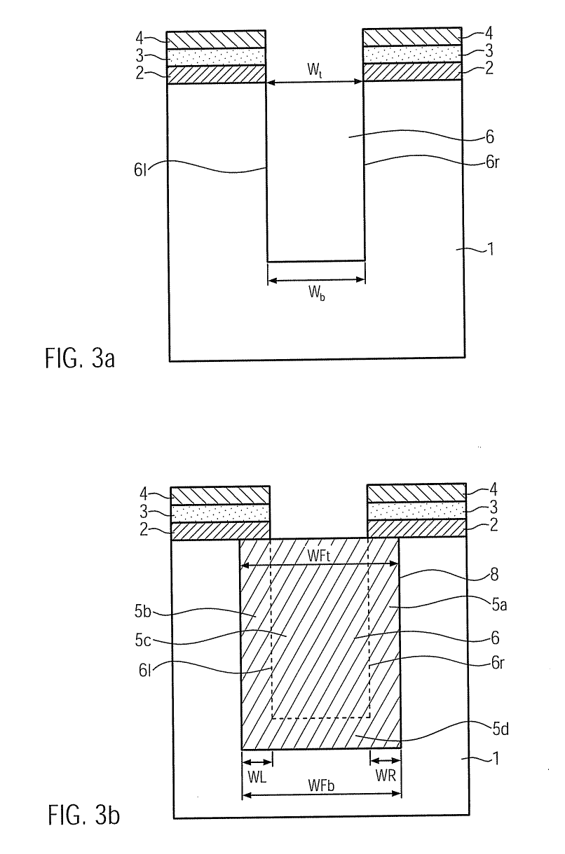

FIG. 3 schematically displays a process for the formation of an isolation trench according to an embodiment of the present invention. In particular, FIG. 3a displays a cross section of the fabrication of a trench 6 in a semiconductor layer 1, while FIG. 3b displays a cross section of the formation of an isolation trench 8 in the semiconductor layer 1 in correspondence to the trench 6 shown in FIG. 3a.

The fabrication of the trench 6 in the semiconductor layer 1 may be performed in several ways, depending, for example, from the materials involved and from the final desired morphology. As an example, one of the possible ways of fabricating a trench 6 in a semiconductor layer 1 is described. The semiconductor layer 1 is covered by a protective layer 2, for instance, by a layer 2 of field oxide FOX. The so-called hard mask (HM) is realized. In particular, a layer of nitride 3 is deposited and a layer 4 of deposited-oxide, for instance a layer of oxide TEOS (tetraethyl ortosilicate) are deposited. The nitride can be deposited for instance by means of low pressure chemical vapour deposition (LPCVD). Subsequently, a resist layer is deposited (not shown in the Figure) on the oxide layer 4. The resist is patterned, typically by means of photolithography techniques, so as to define the morphological properties of the trench. In particular, by means of the patterning of the resist, the position of the trench on the semiconductor layer 1 and its width are defined. A dry etching process is subsequently performed in order to remove the regions of the hard mask in correspondence with the position of the trench 6 to be realized. In particular, with reference to FIG. 3a, the regions of the layers 2, 3 and 4 in correspondence of the trench 6 to be realized, are removed. Examples of dry etching processes are plasma etching or reactive ions etching (RIE). After the removal of the regions of the layers 2, 3 and 4 by means of dry etching, the resist layer is removed. At this point, it is possible to attack the semiconductor layer 1 so as to dig the trench. In particular, the semiconductor layer 1 may be attacked by means of plasma etching. Finally, the etching polymers are removed, for example, by means of wet removal techniques.

In a similar way, it is possible to realize more than one trench in the semiconductor layer 1. In particular, in the case that several trenches are to be realized in the semiconductor layer 1, the number, the width and the position of the trenches may be defined by means of the patterning of the resist by means of photolithography techniques.

The trench 6 shown in FIG. 3a comprises a left sidewall 61 and a right sidewall 6r. Moreover, the trench 6 has a top width corresponding to Wt and a bottom width corresponding to Wb. In the trench 6 shown in the Figure, the top width Wt is equal to the bottom width Wb. In this way, the trench 6 displays vertical lateral sidewalls 6l and 6r, i.e. perpendicular with respect to the direction of the surface of the semiconductor layer 1 and parallel. The trench 6 has, accordingly, a constant width corresponding to the mean width W.

The top width Wt may differ from the bottom width Wb either deliberately, i.e. when a trench having frusto-conical vertical cross-section is realized (i.e. the lateral walls 6l and 6r are not parallel), or because of unavoidable fabrication errors. Preferably, the top width Wt differs from the bottom width Wb by 10% or less.

FIG. 3b displays the formation of an isolation trench 8 in correspondence to the trench 6 shown in FIG. 3a. After fabrication of the trench 6, a thermal oxidation process is in fact performed. The thermal oxidation process may be performed at high temperature (for instance, 900° C. to 1200° C.) either exposing the system to an oxygen environment (dry oxidation) or exposing the system to an environment comprising aqueous vapour (wet oxidation).

During the oxidation process, the thermal oxide develops from the walls of the trench 6 at the expense of the semiconductor layer 1 as explained above. In particular, the oxide thermally grows both starting from the surface of the left sidewall 61 of the trench 6 and starting from the surface of the right sidewall 6r of the trench 6. During the thermal oxidation process, the thermal oxide develops at the expense of the semiconductor material of the layer 1 in the region 5a starting from the right sidewall 6r of the trench and fills the original cavity of the trench 6 from the right. At the same time, the same process happens at the left sidewall 61 of the trench 6: the thermal oxide develops at the expense of the semiconductor material of the layer 1 in the region 5b starting from the left sidewall 61 and fills the original cavity of the trench 6 from the left. The process goes on until the original cavity of the trench 6 is completely filled along the entire depth so as to form the isolation trench 8. The dashed line in FIG. 3b displays the original position of the trench 6 within the isolation trench 8. It is observed, that the phenomena of the oxidation of the walls of the trench 6 also involves the bottom of the trench 6 where the region 5d of the semiconductor layer 1 is worn out. At the end of the process, the isolation trench 8 comprises the regions 5a, 5b, 5c and 5d completely occupied by thermal oxide. The regions 5a and 5b have width WR and WL, respectively, and correspond to regions originally occupied by the semiconductor material of the semiconductor layer 1. The region 5c corresponds to the space originally occupied by the trench 6. In particular, the right half of the region 5c is occupied by thermal oxide grown on the right sidewall 6r of the trench 6, while the left side of the region 5c is occupied by thermal oxide grown on the left sidewall 61 of the trench 6. Finally, the region 5d corresponds to a region originally occupied by the semiconductor material of the semiconductor layer 1 below the bottom of the trench 6. The isolation trench has a top width corresponding to WFt and a bottom width corresponding to WFb. In the case shown in FIG. 3a, the top width WFt coincides with the bottom width WFb and coincides therefore with the final width WF of the isolation trench 8. Preferably, the top width WFt differs from the bottom width WFb by 10% or less.

In the following example, the process of formation of an isolation trench having vertical sidewalls and final width WF according to an embodiment of the present invention is considered.

The width WF of the trench 6 to be fabricated and the thickness T_{OX} of the thermal oxide to be grown may be obtained starting from the value of the final width WF of the isolation trench 8 and from the relationship between the thickness T_{S} of semiconductor material worn out and the thickness T_{OX} of thermal oxide grown.

In particular, considering that the thermal oxidation process occurs on both the right and left sidewalls 6r and 61 of the trench 6, the final width WF of the isolation trench 8 corresponds to twice the thickness T_{OX} of the thermal oxide grown on each of the sidewalls:

WF=2·T_{OX} e4

and, therefore:

$${T}_{OX} = \frac{WF}{2} \qquad e5$$

In other words, in order to obtain an isolation trench having width WF, an oxidation with a thickness T_{OX} corresponding to half of WF is performed.

Moreover, the width W of the trench 6 is occupied by the thermal oxide grown starting from the level of both the sidewalls 6r and 6l of the trench, and therefore:

W=2·H_{OX} e6

wherein H_{OX} is the height of the thermal oxide grown measured from the level of each of the sidewalls 6r and 6l of the trench 6.

Inserting the value of H_{OX} from equation e3 into the equation e6, one obtains:

$$W = 2 \cdot \frac{100 - P}{100} \cdot {T}_{OX} \qquad e7$$

wherein T_{OX} is the total thickness of the thermal oxide grown and P is the percentage fraction of the thickness of semiconductor material worn out related to the total thickness T_{OX}.

Moreover, inserting the value of T_{OX} from the equation e5 into equation e7, one obtains:

$$W = \frac{100 - P}{100} \cdot WF \qquad e8$$

Considering a semiconductor material whose P value corresponds to 40 such as, for example, in the case of silicon, and placing the value into equations e7 and e8, one obtains:

W=1.2·T_{OX} e9

and:

W=0.6·WF e10

In synthesis, in case the semiconductor layer 1 comprises material having P=40, in order to obtain an isolation trench 8 having a final width WF completely filled with thermal oxide, a trench 6 having width W corresponding to 60% WF is fabricated and a thermal oxidation width thickness T_{OX} corresponding to half WF is performed.

The thickness T_{OX} of the oxidation can be adjusted varying for example, the parameters of the thermal oxidation process such as the oxidation temperature, the duration of the oxidation, the pressure of the oxygen and/or of the aqueous vapour and so on.

Even if the method above described refers to a single isolation trench, according to the present invention it is possible to realize on the semiconductor layer 1 any number of isolation trenches. The position of the isolation trenches may be determined, for example, properly patterning the resist and forming the trenches in the semiconductor layer in correspondence to the positions wherein the isolation trenches by means of the thermal oxidation are to be subsequently formed.

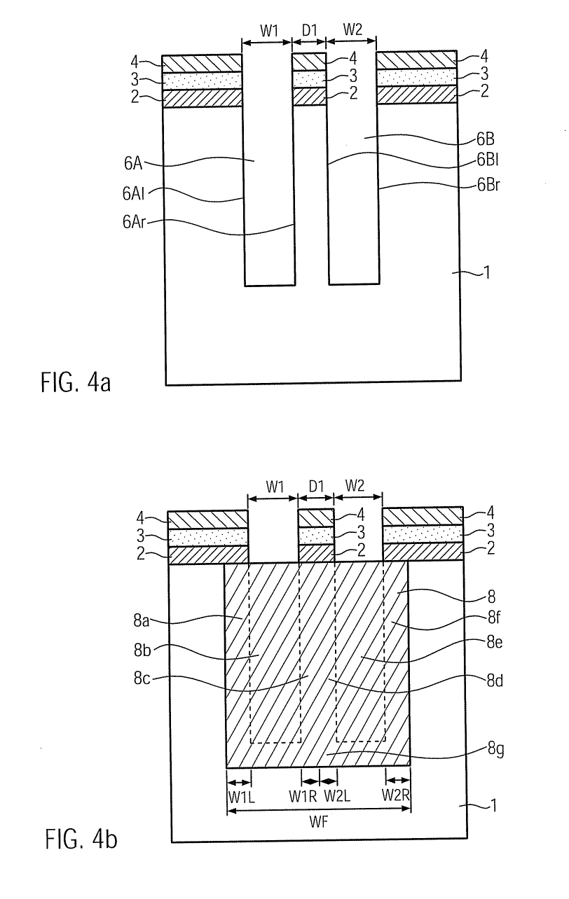

FIG. 4 displays a further embodiment of the present invention.

FIG. 4a displays a cross section of the fabrication process of a first trench 6A and a second trench 6B in a semiconductor layer 1. The first trench 6A and the second trench 6B may be fabricated, for example, in a similar way as described with reference to FIG. 3a for the fabrication of the trench 6. In particular, the dimensions and the reciprocal positions of the first trench 6A and of the second trench 6B may be adjusted properly patterning the resist layer by means of the photolithography techniques.

The first trench 6A has a width W1. In particular, the first trench 6A comprises a left sidewall 6Al and a right sidewall 6Ar. The sidewalls 6Al and 6Ar are parallel and vertical and they are placed at a mutual distance corresponding to W1.

The second trench 6B has a width W2 and comprises a left sidewall 6B1 and a right sidewall 68r. The sidewalls 6Bl and 6Br are parallel and vertical and are placed at a mutual distance W2.

The second trench 6B is placed at a lateral distance D1 from the first trench 6A. In particular, the left sidewall 6Bl of the second trench 6B is parallel to the right sidewall 6Ar of the first trench 6A and it is placed at a distance D1 from same. The space with thickness corresponding to D1 between the first trench 6A and the second trench 6B is occupied by the semiconductor material of the semiconductor layer 1.

The distance D1 is chosen in such a way that the execution of a thermal oxidation process allows the complete oxidation of the space having thickness D1 between the first trench 6A and the second trench 6B so as to completely occupy it with thermal oxide.

FIG. 4b displays the formation of the isolation trench 8 in correspondence to the trenches 6A and 6B shown in FIG. 4a.

After the fabrication of the trenches 6A and 6B, a thermal oxidation process is performed. The thermal oxidation process may be performed at high temperature (for instance, 900° C. to 1200° C.) either exposing the system to an oxygen environment (dry oxidation) or exposing the system to environment comprising aqueous vapour (wet oxidation).

During the oxidation process, the thermal oxide develops starting from the walls of the trenches 6A and 6B at the expense of the material of the semiconductor layer 1. In particular, the oxide thermally grows both from the left sidewall 6Al and from the right sidewall 6Ar of the first trench 6A. Similarly, the oxide thermally grows both from the left sidewall 6B1 and from the right sidewall 6Br of the second trench 6B.

During the thermal oxidation process, the thermal oxide develops at the expense of the semiconductor material of the layer 1 in the region 8a starting from the left sidewall 6Al of the first trench 6A and it fills the original cavity of the first trench 6A from the left. At the same time, the same process occurs at the right sidewall 6Ar of the first trench 6A: the thermal oxide develops at the expense of the semiconductor material of the layer 1 in the region 8c starting from the right sidewall 6Ar and it fills the original cavity of the first trench 6A from the right.

Similarly, the thermal oxide develops at the expense of the semiconductor material of the layer 1 in the region 8d starting from the left sidewall 6Bl of the second trench 6B and it fills the original cavity of the second trench 6B from the left. At the same time, the same process occurs at the right sidewall 6Br of the second trench 6B: the thermal oxide develops at the expense of the semiconductor material of the layer 1 in the region 8f starting from the right sidewall 6Br and it fills the original cavity of the second trench 6B from the right.

When the oxidation is completed, the regions 8c and 8d of the thermal oxide completely occupy the space having thickness D1 originally occupied by the semiconductor material between the trenches 6A and 6B. Moreover, the cavities of the trenches 6A and 6B are completely filled by thermal oxide.

The dashed line in FIG. 4b shows the original position of the trenches 6A and 6B within the isolation trench 8. It is observed that the oxidation phenomena of the walls of the trenches 6A and 6B also involves the bottom of the trenches 6A and 6B where the region 8g of the semiconductor layer 1 is worn out.

At the end of the process, the isolation trench 8 comprises the regions 8a, 8b, 8c, 8d, 8e, 8f and 8g completely filled with thermal oxide. The regions 8a, 8c, 8d, and 8f have width W1L, W1R, W2L and W2R, respectively, and correspond to the regions originally occupied by the semiconductor material of the semiconductor layer 1.

Regions 8b and 8e correspond to the space originally occupied by the trenches 6A and 6B, respectively. In particular, the right half of the region 8b is occupied by thermal oxide grown on the right sidewall 6Ar of the trench 6A, while the left half of the region 8b is occupied by thermal oxide grown on the left sidewall 6Al of the trench 6A. The right half of the region 8e is occupied by thermal oxide grown on the right sidewall 6Br of the trench 6B, while the left half of the region 8e is occupied by thermal oxide grown on the left sidewall 6Bl of the trench 6B.

Finally, the region 8g corresponds to a region originally occupied by the semiconductor material of the semiconductor layer 1 below the bottom of the trenches 6A and 6B.

The isolation trench 8 so formed has a width corresponding to WF.

According to the present invention, the number of trenches to be realized in the semiconductor layer 1 is not limited to two. It is, in fact, possible to fabricate any number of adjacent trenches and to subsequently perform the thermal oxidation process in a similar way to what is described so as to obtain the isolation trench filled with thermal oxide.

In the following example, the formation process of an isolation trench 8 having vertical walls and final width WF according to an embodiment of the present invention, is considered.

The case wherein two adjacent trenches 6A and 6B having the same width (W1=W2) is considered wherein the two trenches are placed at a lateral distance D1 as schematically shown in FIG. 4a.

The value of W1=W2, of D1 and of the thickness T_{OX} of thermal oxide to be grown may be obtained from the value of the final width WF of the isolation trench 8 and from the relation between the thickness T_{S} of semiconductor material worn out and the thickness T_{OX} of thermal oxide grown.

In particular, considering that the thermal oxidation process occurs on both right and left sidewalls 6Ar, 6Al, 6Br, 6B1 of both the trenches 6A and 6B, the final width WF of the isolation trench 8 corresponds to 4 times the thickness T_{OX} of thermal oxide grown on each of the sidewalls:

WF=4·T_{OX} e11

Consequently:

$${T}_{OX} = \frac{WF}{4} \qquad e12$$

In other words, in order to obtain an isolation trench having a width WF, a thermal oxidation with thickness T_{OX} corresponding to one fourth of WF is performed.

The width W1 of the trench 6A and the width W2 of the trench 6B are occupied by the thermal oxide grown starting from the level of both the sidewalls 6Ar, 6Al, 6Br and 6Bl of the trenches and therefore:

W1=W2=2·H_{OX} e13

wherein H_{OX} is the height of the thermal oxide grown measured from the level of each sidewall 6Ar, 6Al, 6Br and 6Bl of the trenches 6A and 6B.

Inserting the value of H_{OX} from equation e3 into equation e13, one obtains:

$$W 1 = W 2 = 2 \cdot \frac{100 - P}{100} \cdot {T}_{OX} , \qquad e14$$

wherein T_{OX} is the total thickness of the thermal oxide grown and P is the percentage fraction of the thickness of semiconductor material worn out with respect to the total thickness T_{OX}.

Moreover, inserting the value of T_{OX} from equation e12 into equation e14, one obtains:

$$W 1 = W 2 = \frac{100 - P}{200} \cdot WF \qquad e15$$

Since the volume having thickness D1 of semiconductor material is converted into thermal oxide as a consequence of the oxidation of the right sidewall 6Ar of the trench 6A and the left sidewall 6Bl of the trench 6B, the distance D1 corresponds to twice the thickness of semiconductor worn out as a consequence of the thermal oxidation:

$$D 1 = 2 \cdot \frac{P}{100} \cdot {T}_{OX} \qquad e16$$

Inserting the value of T_{OX} from equation e12 into equation e16, one obtains:

$$D 1 = \frac{P}{200} \cdot WF \qquad e17$$

In the case wherein the semiconductor material has a value of P corresponding to 40 suggests, for example, in the case of silicon, from equations e14 and e15 one obtains:

W1=W2=1.2·T_{OX} e18

and:

W1=W2=0.3·WF e19:

As far as D1 is concerned, from equations e16 and e17 one obtains:

D1=0.8·T_{OX} e20

and:

D1=0.2·WF e21

In synthesis, in the case wherein the semiconductor layer consists of material having P=40, in order to obtain an isolation trench 8 having final width WF completely filled with thermal oxide, two trenches 6A and 6B having the same width W1=W2 corresponding to 30% of WF are fabricated and they are placed at a lateral distance D1 corresponding to 20% of WF, and an thermal oxidation with thickness T_{OX} corresponding to one fourth of WF is performed.

The thickness T_{OX} of the oxidation may be adjusted, for instance, varying the parameters of the thermal oxidation process such as the oxidation temperature, the duration of the oxidation, the pressure of oxygen and/or of aqueous vapour and so on.

Even if the method described above refers to a single isolation trench, according to the present invention it is possible to realize on the semiconductor layer 1 any number of isolation trenches. The position of the isolation trenches may be fixed for example, properly patterning the resist and forming the pairs of adjacent trenches or the groups of adjacent trenches in the semiconductor layer in correspondence to the positions wherein the isolation trench are subsequently to be formed by means of the thermal oxidation.

Moreover, if the number of adjacent trenches is increased, being the thickness T_{OX} of thermal oxide grown during the thermal oxidation equal, one obtains isolation trenches having different dimensions. It is accordingly possible to realize on the same semiconductor layer 1 several isolation trenches having different widths by means of a single thermal oxidation process simply fabricating on the semiconductor layer 1 several groups of adjacent trenches comprising several numbers of trenches. In correspondence to the single trenches or to the pairs of trenches, the isolation trenches having minimum widths are formed, in correspondence to the numerous groups of adjacent trenches, the isolation trenches having higher widths are formed.

According to a further embodiment of the present invention, an isolation trench 8 completely filled with thermal oxide and having a final width WF is formed starting from an array of N trenches wherein each trench has a width corresponding to WT and the trenches are separated from each other by a distance D.

The values of WT, D and of the thickness T_{OX} of thermal oxide to be grown may be determined starting from the value of the final width WF of the isolation trench 8 and from the relation between the thickness T_{S} of semiconductor material grown out and the thickness T_{OX} of thermal oxide grown.

In particular, considering that the thermal oxidation process occurs on both the left and right sidewalls of each of the N trenches, the final width WF of the isolation trench 8 corresponds to 2N times the thickness T_{OX} of thermal oxide grown on each of the sidewalls:

WF=2N·T_{OX} e22

Consequently:

$${T}_{OX} = \frac{WF}{2 N} \qquad e23$$

In other words, in order to obtain an isolation trench having width WF, a thermal oxidation with thickness T_{OX} corresponding to WF divided by twice the number N of trenches of the array is performed.

The width W of each of the N trenches is occupied by the thermal oxide grown from the level of both sidewalls of the trench, therefore:

W2·H_{OX} e24

wherein H_{OX} is the height of the thermal oxide grown measured from the level of each sidewall of each trench.

Inserting the value of H_{OX} from equation e3 into equation e24, one obtains:

$$W = 2 \cdot \frac{100 - P}{100} \cdot {T}_{OX} \qquad e25$$

wherein T_{OX} is the total thickness of the thermal oxide grown and P is the percentage fraction of thickness of semiconductor material worn out with respect to the total thickness T_{OX}.

Moreover, inserting the value of T_{OX} from equation e23 into equation e25, one obtains:

$$W = \frac{100 - P}{100 N} \cdot WF . \qquad e26$$

Since the volume having thickness D of semiconductor material between the trenches is converted into thermal oxide as a consequence of the oxidation of the right sidewall of a trench and of the left sidewall of the adjacent trench, the distance D corresponds to twice the thickness of semiconductor worn out as a consequence of the thermal oxidation:

$$D = 2 \cdot \frac{P}{100} \cdot {T}_{OX} \qquad e27$$

Inserting the value of T_{OX} from equation e23 into equation e27, one obtains:

$$D = \frac{P}{100 N} \cdot WF . \qquad e28$$

In the case that the semiconductor material has a value P corresponding to 40 such as, for example, in the case of silicon, from equations e25 and e26, one obtains:

$$\begin{matrix}W = 1.2 \cdot {T}_{OX} & e29 \\ and \text{:} & \\ W = \frac{0.6}{N} \cdot WF . & e30\end{matrix}$$

As far as D is concerned, from equations e27 and e28 one obtains:

$$\begin{matrix}D = 0.8 \cdot {T}_{OX} & e31 \\ and \text{:} & \\ D = \frac{0.4}{N} \cdot WF . & e32\end{matrix}$$

In synthesis, in case the semiconductor layer 1 consists of material having P equal to 40, in order to obtain an isolation trench 8 having final width WF completely filled by thermal oxide, an array of N trenches having the same width W equal to 60/N percent of WF and placed at a lateral distance D equal to 40/N percent of WF is fabricated and a thermal oxidation with thickness T_{OX} equal to WF divided by twice the number N of trenches of the array is performed.

The thickness T_{OX} of the oxidation may be adjusted varying, for example, the parameters of the thermal oxidation process such as the oxidation temperature, the duration of the oxidation, the pressure of oxygen and/or of aqueous vapour and so on.

In general, according to an embodiment of the present invention, in case an isolation trench with width WF completely filled with thermal oxide is to be realized in a semiconductor material layer whose value P of the percentage fraction of the thickness of semiconductor material worn out with respect to the total thickness T_{OX} of thermal oxide grown is known, one establishes the number N of trenches to be formed into the semiconductor layer and the thickness of the oxidation T_{OX}, the width W of the trenches and their mutual distance D are determined by means of equations e23, e26 and e28, respectively.

In the case that the semiconductor layer consists of silicon (P=40), the thickness T_{OX} of the oxidation, the width W of the trenches and their mutual distance D can be obtained by means of equations e23, e30 and e32, respectively.

Even if the method described above refers to a single isolation trench, according to the present invention it is possible to fabricate on the semiconductor layer 1 any number of isolation trenches. The position of the isolation trenches may be determined, for instance, properly patterning the resist informing the arrays of adjacent trenches into the semiconductor layer in correspondence to the positions wherein the isolation trenches by means of thermal oxidation are to be subsequently formed.

Moreover, varying the number N of adjacent trenches in the array, being the thickness of thermal oxide T_{OX} grown during the thermal oxidation equal, one obtains isolation trenches having several dimensions. From equation e22, it is in fact possible to observe that the final WF of the trenches, being the thickness T_{OX} of thermal oxide grown during the thermal oxidation equal, varies by varying N. It is accordingly possible to realize on the same semiconductor layer 1, several isolation trenches having different widths by means of a single thermal oxidation process simply fabricating on the semiconductor layer 1 several arrays of adjacent trenches comprising several numbers N of trenches. In correspondence to the less numerous arrays, the isolation trenches having minimum widths are formed, in correspondence to the arrays more numerous, the wider isolation trenches are formed.

Therefore, by means of the present invention it is possible to realize in an easy way isolation trenches completely filled with thermal oxide and very large (for instance, several micrometers) even performing thermal oxidation processes allowing to grow small thicknesses of thermal oxide (for instance, in the order of 100 nm). The final width of the isolation trenches is obtained, for instance, increasing the number N of adjacent trenches in the trench arrays.

In the following, some practical examples of application of the method according to the present invention are described.

The bipolar CMOS-DMOS device BCD6 is provided with an isolation trench having a thickness of 2.5 μm fabricated in a silicon layer in order to obtain a breakdown voltage BV of 100V.

The isolation trench may be, for instance, fabricated according to the present invention by means of a pair of trenches having width W and placed at a lateral distance D. Considering, therefore, P=40, WF=2.5 μm and N=2, from equations e23, e30 and e32, one obtains: T_{OX}=0.75 μm; W=0.75 μm and D=0.5 μm.

In practice, in order to obtain the trench having thickness 2.5 μm completely filled with thermal oxide, two trenches having width 0.75 μm and separated by 0.5 μm are realized into the silicon layer and a thermal oxidation of 625 nm is performed.

It would be possible to obtain the same result fabricating a number N higher than 2 of trenches into the array. In this case, the thickness of the required thermal oxidation would be lower than 625 nm and the oxidation process could be accelerated.

If, on the contrary, it would be necessary to realize in a silicon layer an isolation trench having a width equal to 3 μm by means of two trenches having width W and spaced by D, considering P=40, WF=3.0 μm and N=2, from equations e23, e30 and e32, one obtains: T_{OX}=0.75 μm; W=0.9 μm and D=0.6 μm.

In practice, in order to obtain the trench having width 3 μm completely filled with thermal oxide, it is necessary to realize into the silicon layer two trenches having width 0.9 μm and spaced by 0.6 μm and to perform a thermal oxidation of 750 nm.

Even in this case, it would be possible to obtain the same result fabricating a number N higher than 2 of trenches into the array. In this case, the thickness of the thermal oxidation required would be lower than 750 nm and the oxidation process could be accelerated.

In general, it is necessary to find a compromise between the number N of trenches to be fabricated into the semiconductor layer and the width of thermal oxide to be grown by means of the thermal oxidation process.

Furthermore, by means of the present invention, it is possible to realize several isolation trenches having different widths by means of a single thermal oxidation process simply varying the layout of the trenches dug into the semiconductor layer. If, for example, a trench having width 750 nm, an array comprising two trenches having widths 0.9 μm and spaced by 0.6 μm and an array comprising three trenches having widths 0.9 μm and spaced by 0.6 μm are fabricated in a semiconductor layer and a single thermal oxidation with a thickness of 625 nm is performed, an isolation trench with width 125 μm, an isolation trench with width 2.5 μm and an isolation trench with width 3.75 μm are respectively obtained.

The method according to the present invention allows obtaining isolation trenches having several depths. In particular, the depth of the trenches obtainable is not limited by the method according to the present invention, but it rather depends on the chemistry of the etching process of the semiconductor layer 1 employed in the fabrication step of the trenches. It could be, for example, possible to realize trenches having depths from about 1 μm to about 150 μm according to the application of the device. The method according to the present invention allows therefore also obtaining trenches having depths in the order of 150 μm completely filled with thermal oxide.

The method according to the present invention allows obtaining isolation trenches completely filled with thermal oxide by means of only one thermal oxidation step. In particular, according to the present invention it is not necessary to deposit into the trenches deposited-oxide. On the contrary, the entire volume of the trench is occupied by thermal oxide. This not only accelerates and renders more efficient and inexpensive the production process of isolation trenches, but it also allows obtaining isolation trenches with high morphological and functional properties. In fact, the thermal oxide is better than the deposited-oxide, both from the electric point of view and from the morphologic point of view. Moreover, by means of the method of the present invention, there is no limit for the width of the isolation oxide: the fabrication of arrays comprising an appropriate number of adjacent trenches and the subsequent thermal oxidation allow easily obtaining isolation trenches even very wide. The method according to the present invention allows moreover to further accelerate the formation process of isolation trenches since, differently from the method based on the deposition of oxide, it is not necessary to perform any final polishing process. According to the method of the present invention, in fact, the thermal oxide grown fills the trenches and, contrary to what happens during deposition of oxide, it does not grow in other regions of the device where the presence of oxide is not wanted and where it could even compromise the functionality of the device. Moreover, the method of the present invention allows obtaining isolation trenches geometrically well defined avoiding the problems concerning, for example, the formation of defects typical of deposition techniques such as, for example, the so-called bird beaks. In particular, the volume of thermal oxide is fixed by the number and the geometry of the trenches initially dug into the semiconductor layer because thermal oxidation occurs completely at the expense of the semiconductor material interposed between the trenches and/or at the sides of the trenches. This allows the high precision control in the designing phase of the final geometry of the isolation trench. By means of the present invention, in fact, it is possible to avoid loss of area since the thermal oxidation involves the sacrificial semiconductor material whose geometry is established when the trenches layout is designed. Moreover, the method according to the present invention is extremely flexible and allows satisfying requests for isolation trenches having different widths with a single thermal oxidation process simply varying the number and the geometry of the adjacent trenches in the initial semiconductor layer. The structures obtained with the method according to the present invention have extremely vertical and precise geometries. The vertical geometries are particularly advantageous because this allows the minimization of the waste of semiconductor material in the semiconductor layer. In particular, for example, in case of systems comprising several devices on the same chip, the realization of isolation trenches having vertical geometries allows an effective isolation to be obtained between the devices, minimizing at the same time the space occupied by the isolation trenches and minimizing, therefore, the total dimensions of the chip.

Even if the present invention has been described with respect to the embodiments disclosed above, it is clear for the person skilled in the art that it is possible to realize several modifications, variations and improvements of the present invention in the light of the teaching described above and within the ambit of the appended claims without departing from the object and the scope of protection of the invention.

For example, it is possible to employ several numbers of adjacent trenches in order to obtain, at least one isolation trench filled with thermal oxide. Moreover, it is possible to fabricate more than one isolation trench on the same semiconductor layer. Moreover, the method according to the present invention may be employed for several kinds of semiconductor layers. For example, it is possible to employ the method according to the present invention for the fabrication of isolation trenches into bulk substrates or epitaxial substrates of semiconductor material. Moreover, it is also possible to employ the method according to the present invention for the fabrication of isolation trenches in thin layers of semiconductor material such as, for example, in the case of SOI systems (silicon on insulator). Moreover, it is possible to employ the method according to the present invention both for realizing thin isolation trenches (shallow trench insulation) and for realizing deep isolation trenches (deep trench insulation).

Consequently, the invention is not limited to the embodiments described above, but it is only limited by the scope of protection of the enclosed claims.

That which is claimed:

1. Method for producing at least one trench insulation (8) having a final width (WF) in a semiconductor layer (1), said method comprising the steps of:
fabricating into the semiconductor layer (1) at least a first trench (6A) and a second trench (68), said second trench (6B) being at a lateral distance (D1) from said first trench (6A); and
performing a thermal oxidation process,
wherein said lateral distance (D1) is adapted to completely oxidize the space between said first trench (6A) and said second trench (6B) by means of the thermal oxidation of the side walls (6Ar) of said first trench (6A) and of the side walls (6Bl) of said second trench (6B) so as to obtain a single trench insulation (8) having said final width (WF).

2. Method according to claim 1, wherein said lateral distance (D1) is equal to 20 percent or less of said final width (WF).

3. Method according to claim 1, wherein said first trench (6A) has a width (W1) smaller than said final width (WF) and said width (W1) of said first trench (6A) is adapted to completely fill said first trench (6A) by means of the thermal oxidation of the side walls (6Al; 6Ar) of said first trench (6A) so as to obtain the single trench insulation (8) having said final width (WF).

4. Method according to claim 3, wherein said second trench (6B) has a width (W2) smaller than said final width (WF) and said width (W2) of said second trench (6B) is adapted to completely fill said second trench (6B) by means of the thermal oxidation of the side walls (6Bl; 6Br) of said second trench (6B) so as to obtain the single trench insulation (8) having said final width (WF).

5. Method according to claim 4, wherein said width (W1) of said first trench (6A) is substantially equal to said width (W2) of said second trench (6B).

6. Method according to claim 4, wherein said width (W1) of said first trench (6A) and said width (W2) of said second trench (6B) are 30 percent or less of said final width (WF).

7. Method according to claim 1, comprising the following steps:
fabricating an array of N trenches into said semiconductor layer (1) with N≧2, each of said trenches having a trench width (WT) and said trenches being laterally separated by a mutual distance (D), wherein the trench width (WT) of said trenches and the mutual distance (D) between the trenches are adapted to completely oxidize the regions between the trenches and to completely fill each of said trenches by means of the thermal oxidation of the side walls of each of said trenches so as to obtain the single trench insulation (8) having said final width (WF).

8. Method according to claim 7, wherein said trench width (WT) of each of said N trenches is 60/N percent or less of said final width (WF).

9. Method according to claim 7, wherein said mutual distance (D) is 40/N percent or less of said final width (WF).

10. Method for producing at least one trench insulation (8) having a final width (WF) in a semiconductor layer (1), said method comprising the steps of:
fabricating at least a trench (6) into the semiconductor layer (1), said trench (6) having a top width (Wt) and a bottom width (Wb), wherein said top width (Wt) and said bottom width (Wb) are smaller than said final width (WF) of said trench insulation (8); and
performing a thermal oxidation process,
wherein said top width (Wt) and said bottom width (Wb) of said trench (6) are adapted to completely fill said trench (6) along its entire depth by means of the thermal oxidation of the sides (6l; 6r) of said trench (6) so as to obtain a single trench insulation (8) having said final width (WF).

11. Method according to claim 10, wherein said top width (Wt) of said trench (6) differs from said bottom width (Wb) of said trench (6) by 10 percent or less.

12. Method according to claim 10, wherein at least one of said top width (Wt) and said bottom width (Wb) of said trench (6) is 60 percent or less of said final width (WF).

13. A semiconductor device comprising at least one trench insulation (8), said trench insulation having a top width (WFt) and a bottom width (WFb), wherein said top width (WFt) differs from said bottom width (WFb) by 10 percent or less and said trench insulation (8) is completely filled by thermal oxide.

14. A semiconductor device according to claim 13, wherein at least one of said top width (WFt) and said bottom width (WFb) is larger than or equal to 2.5 μm.

15. A semiconductor device according to claim 13, wherein said semiconductor device comprises a Bipolar-CMOS-DMOS BCD device.
